(19) United States
(12) Patent Application Publication
(10) Pub. No.: US 2026/0104463 A1
(43) Pub. Date: Apr. 16, 2026

(54) MULTISYSTEM LEVEL BATTERY ENERGY STORAGE SYSTEM LIFE MODEL ESTIMATION

(71) Applicant: Fluence Energy, LLC, Arlington, VA (US)

(72) Inventors: Amy Bohinsky, Austin, TX (US); Richard James Prevost, JR., Herndon, VA (US); John Thomas Guerin, Los Alamitos, CA (US); Mehran Dibaji, Quincy, MA (US)

(73) Assignee: Fluence Energy, LLC, Arlington, VA (US)

(21) Appl. No.: 19/359,105

(22) Filed: Oct. 15, 2025

Related U.S. Application Data
(60) Provisional application No. 63/708,118, filed on Oct. 16, 2024.

(51) Int. Cl. G01R 31/367; G01R 31/392; G01R 31/396; G06F 17/18; H01M 10/42

(52) U.S. Cl. CPC G01R 31/367; G01R 31/392; G01R 31/396; G06F 17/18; H01M 10/4285

(57) ABSTRACT

A method for estimating and controlling a battery energy storage system (BESS) life model. Receiving a BESS life model that estimates an expected remaining useful life of the BESS at multiple hierarchical levels. The BESS life model is generated by a process including constructing a cell-level degradation model based on laboratory test data representing degradation behavior of a plurality of battery cells; generating cell life predictions by executing a Monte Carlo simulation; aggregating the cell life predictions into pack life models by selecting a worst-performing cell; aggregating the pack life models into a node life model; and generating a system-level life estimate based on the node life model. Adjusting an operational parameter of the BESS based on the received BESS life model, wherein the operational parameter includes one or more of a charge rate, a discharge rate, a depth of discharge, a cooling system setpoint, and a module-level balancing.

### CROSS-REFERENCE TO RELATED APPLICATIONS

This application claims the benefit of U.S. Provisional Application No. 63/708,118, filed Oct. 16, 2024, which is hereby incorporated by reference in its entirety.

### INTRODUCTION

The concepts described herein relate generally to battery energy storage systems, and more specifically, to performance estimation at multisystem levels based upon laboratory modeling.

Modular battery energy storage systems include multiple individual energy storage enclosures interconnected to provide varied levels of storage capacity. Energy storage systems can be used to store additional power produced by an external power source during periods of reduced demand and provide additional power to external power sources during periods of increased demand.

Each individual energy storage enclosure includes multiple battery packs. Each battery pack includes multiple modules made up of individual battery cells disposed adjacent to one another. Battery modules, while potentially constructed using the same type and amount of material, may provide varying amounts of power because of a lower performing cell within a module. Further, a pack may contain multiple series coupled battery modules, an enclosure/cube that may contain multiple parallel coupled packs, a node may contain one or more enclosures/cubes, and a core may contain multiple parallel coupled nodes.

Thus, a site system made up of one or more cores containing nodes that contain packs that contain individual cells may be limited due to a worst performing cell. Thus, it would be advantageous to provide an optimized system and method to predict not only an individual battery cell life, but also the ability to predict life performance at the pack, node, core, and site levels.

### SUMMARY

Disclosed herein are systems regarding energy storage enclosure systems and methods for battery energy storage system (BESS) life model estimation.

An aspect of the disclosure may include a method for estimating and controlling a battery energy storage system (BESS) life model, the method includes: receiving, by a controller, a BESS life model that estimates an expected remaining useful life of the BESS at multiple hierarchical levels, where the BESS life model is generated by a process comprising: constructing a cell-level degradation model based on laboratory test data representing degradation behavior of a plurality of battery cells, where the degradation model accounts for variations in cell capacity, internal resistance, and temperature-dependent aging; generating a plurality of cell life predictions by executing a Monte Carlo simulation that provides, as inputs to the cell-level degradation model, a plurality of random samples from a cycle temperature distribution, a calendar temperature distribution, and a beginning-of-life cell capacity distribution; aggregating the plurality of cell life predictions into a plurality of pack life models for a plurality of battery packs within the BESS by selecting a worst-performing cell based on predicted remaining useful life; aggregating the plurality of pack life models into a node life model for a node within the BESS, where the node comprises multiple parallel-coupled ones of the plurality of battery packs; and generating a system-level life estimate, including a statistical confidence interval, based on the node life model. The method further includes adjusting, by the controller, an operational parameter of the BESS based on the received BESS life model, wherein the operational parameter comprises one or more of a charge rate, a discharge rate, a depth of discharge, a cooling system setpoint, and a module-level balancing.

Another aspect of the disclosure may include a method for BESS life model estimation. The method may include generating, based on laboratory testing, a set of battery performance data from a plurality of BESS battery cells including generating, based on the set of battery performance data, a life model for a plurality of individual battery cells for use in a BESS. The method may include generating, based on a battery cell thermal model and operational data, a cycle temperature distribution model and a calendar temperature distribution model and may also include generating, based on a random sample of the cycle temperature distribution model, the calendar temperature distribution model, and a beginning of life cell capacity distribution model, a model input comprising a cycle temperature, a calendar temperature, and a cell capacity, to the life model. The method may continue by generating a plurality of model inputs to the life model based upon a plurality of random samples of the cycle temperature distribution model, the calendar temperature distribution model, and the beginning of life cell capacity distribution model, and also generating, by the life model, a BESS life estimate further comprising a confidence interval.

Another aspect of the disclosure may further include generating, by the life model, a plurality of module life models for a plurality of modules within the BESS, wherein each of the plurality of modules comprises multiple ones of the plurality of battery cells.

Another aspect of the disclosure may further include generating, by the life model, at least two pack life models for at least two packs within the BESS, wherein each of the at least two packs comprises multiple parallel-coupled ones of the plurality of modules.

Another aspect of the disclosure may further include generating, by the life model, at least two cube life models for at least two cubes within the BESS, wherein each of the at least two cubes comprises multiple parallel-coupled ones of the at least two packs.

Another aspect of the disclosure may further include generating, by the life model, at least two node life models for at least two nodes within the BESS, wherein each of the at least two nodes comprises multiple parallel-coupled ones of the at least two cubes.

Another aspect of the disclosure may further include generating, by the life model, at least two core life models for at least two cores within the BESS, wherein each of the at least two cores comprises multiple parallel-coupled one of the at least two nodes.

Another aspect of the disclosure may further include each of the at least two pack life models is based on a worst performing cell within the respective pack.

Another aspect of the disclosure may further include each of the at least two cube life models is based on a worst performing pack within the respective cube.

Another aspect of the disclosure may further include each of the at least two pack life models is based on an additional Monte Carlo simulation.

Another aspect of the disclosure may further include the additional Monte Carlo simulation is based upon a combination of multiprocessing and multithreading computations.

An aspect of the disclosure may include a system for estimating and controlling a battery energy storage system (BESS) life model. The system includes a controller operational to receive a BESS life model that estimates an expected remaining useful life of the BESS at multiple hierarchical levels, where the BESS life model is generated by a process comprising: constructing a cell-level degradation model based on laboratory test data representing degradation behavior of a plurality of battery cells, where the degradation model accounts for variations in cell capacity, internal resistance, and temperature-dependent aging; generating a plurality of cell life predictions by executing a Monte Carlo simulation that provides, as inputs to the cell-level degradation model, a plurality of random samples from a cycle temperature distribution, a calendar temperature distribution, and a beginning-of-life cell capacity distribution; aggregating the plurality of cell life predictions into a plurality of pack life models for a plurality of battery packs within the BESS by selecting a worst-performing cell based on predicted remaining useful life; aggregating the plurality of pack life models into a node life model for a node within the BESS, where the node comprises multiple parallel-coupled ones of the plurality of battery packs; and generating a system-level life estimate, including a statistical confidence interval, based on the node life model. The controller is further operational to adjust an operational parameter of the BESS based on the received BESS life model, where the operational parameter comprises one or more of a charge rate, a discharge rate, a depth of discharge, a cooling system setpoint, and a module-level balancing.

Another aspect of the system may include where the controller is further configured to generate, by the life model, a plurality of module life models for a plurality of modules within the BESS, wherein each of the plurality of modules comprises multiple ones of the plurality of battery cells.

Another aspect of the system may include where the controller is further configured to generate, by the life mode, at least two pack life models for at least two packs within the BESS, wherein each of the at least two packs comprises multiple parallel-coupled ones of the plurality of modules.

Another aspect of the system may include where the controller is further configured to generate, by the life module, at least two cube life models, for at least two cubes within the BESS, wherein each of the at least two cubes comprises multiple parallel-coupled ones of the at least two packs.

Another aspect of the system may include where the controller is further configured to generate, by the life module, at least two node life models, for at least two nodes within the BESS, wherein each of the at least two nodes comprises multiple parallel-coupled ones of the at least two cubes.

Another aspect of the system may include where the controller is further configured to generate, by the life module, at least two core life models for at least two cores within the BESS, wherein each of the at least two nodes comprises multiple parallel-coupled ones of the at least two cubes.

Another aspect of the system may include where each of the at least two pack life models is based on a worst performing cell within the respective pack.

Another aspect of the system may include where each of the at least two node life models is based on a worst performing pack within the respective node.

Another aspect of the system may include where each of the at least two pack life models is based on an additional Monte Carlo simulation.

An aspect of the disclosure may include a method for BESS life model estimation. The method may include generating, based on laboratory testing, a set of battery performance data from a plurality of BESS battery cells including generating, based on the set of battery performance data, a life model for a plurality of individual battery cells for use in a BESS. The method may include generating, based on a battery cell thermal model and operational data, a cycle temperature distribution model and a calendar temperature distribution model and may also include generating, based on a random sample of the cycle temperature distribution model, the calendar temperature distribution model, and a beginning of life cell capacity distribution model, a model input including a cycle temperature, a calendar temperature, and a cell capacity, to the life model. The method may continue by generating a plurality of model inputs to the life model based upon a plurality of random samples of the cycle temperature distribution model, the calendar temperature distribution model, and the beginning of life cell capacity distribution model, and also generating, by the life model, a BESS life estimate that may further include a confidence interval. The method may also include generating, by the life model, a base life model based on a plurality of battery cells while also generating, by the life model, a pack life model, for a pack within a BESS, wherein the pack may include a plurality of series coupled battery modules and where each battery module includes a plurality of battery cells. The method may further include generating, by the life model, a node life model for a node within a BESS, wherein the node includes a plurality of parallel coupled packs, and generating, by the life model, a core life model for a core within a BESS, where the core may include a plurality of parallel coupled nodes. The method may include where the plurality of parallel coupled nodes is electrically coupled utilizing alternating current, where the pack life model is based on a worst performing cell within the pack, and where the node life model is based on a worst performing pack of the plurality of parallel coupled packs within the node.

The above features and advantages, and other features and attendant advantages of this disclosure, will be readily apparent from the following detailed description of illustrative examples and modes for carrying out the present disclosure when taken in connection with the accompanying drawings and the appended claims. Moreover, this disclosure expressly includes combinations and sub-combinations of the elements and features presented above and below.

### BRIEF DESCRIPTION OF THE DRAWINGS

The accompanying drawings, which are incorporated into and constitute a part of this specification, illustrate implementations of the disclosure which, taken together with the description, serve to explain the principles of the disclosure.

FIG. 1 schematically illustrates an energy storage system including a plurality of energy storage enclosures, in accordance with the disclosure.

FIG. 2 is a schematic isometric view of another energy storage system in accordance with one aspect of the disclosure.

FIG. 3 is a schematic front view of the energy storage system in accordance with one aspect of the disclosure.

FIG. 4 is a schematic isometric view of still another energy storage system in accordance with one aspect of the disclosure.

FIG. 5 illustrates a schematic diagram of direct current block enclosures with multiple parallel switched buses, in accordance with one aspect of the disclosure.

FIG. 6 illustrates a cell-level battery degradation algorithm for the generation of BESS life predictions at multiple system levels, in accordance with one aspect of the disclosure.

FIG. 7 illustrates a life estimate with confidence intervals based on a system-level battery degradation algorithm, in accordance with one aspect of the disclosure.

FIG. 8 illustrates a multiprocessing and multithreading technique for a system-level battery degradation algorithm, in accordance with one aspect of the disclosure.

FIG. 9 illustrates a method for BESS life model estimation, in accordance with one aspect of the disclosure.

The appended drawings are not necessarily to scale and may present a somewhat simplified representation of various preferred features of the present disclosure as disclosed herein, including, for example, specific dimensions, orientations, locations, and shapes. Details adjacent to such features will be determined in part by the particular intended application and use environment.

### DETAILED DESCRIPTION

The present disclosure is susceptible of embodiments in many different forms. Representative examples of the disclosure are shown in the drawings and described herein in detail as non-limiting examples of the disclosed principles. To that end, elements and limitations described in the Abstract, Introduction, Summary, and Detailed Description sections, but not explicitly set forth in the claims, should not be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, and the words “including”, “containing”, “comprising”, “having”, and the like shall mean “including without limitation”. Moreover, words of approximation such as “about”, “almost”, “substantially”, “generally”, “approximately”, etc., may be used herein in the sense of “at, near, or nearly at”, or “within 0-5% of”, or “within acceptable manufacturing tolerances”, or logical combinations thereof. As used herein, a component that is “configured to” perform a specified function is capable of performing the specified function without alteration, rather than merely having potential to perform the specified function after further modification. In other words, the described hardware, when expressly configured to perform the specified function, is specifically selected, created, implemented, utilized, programmed, and/or designed for the purpose of performing the specified function.

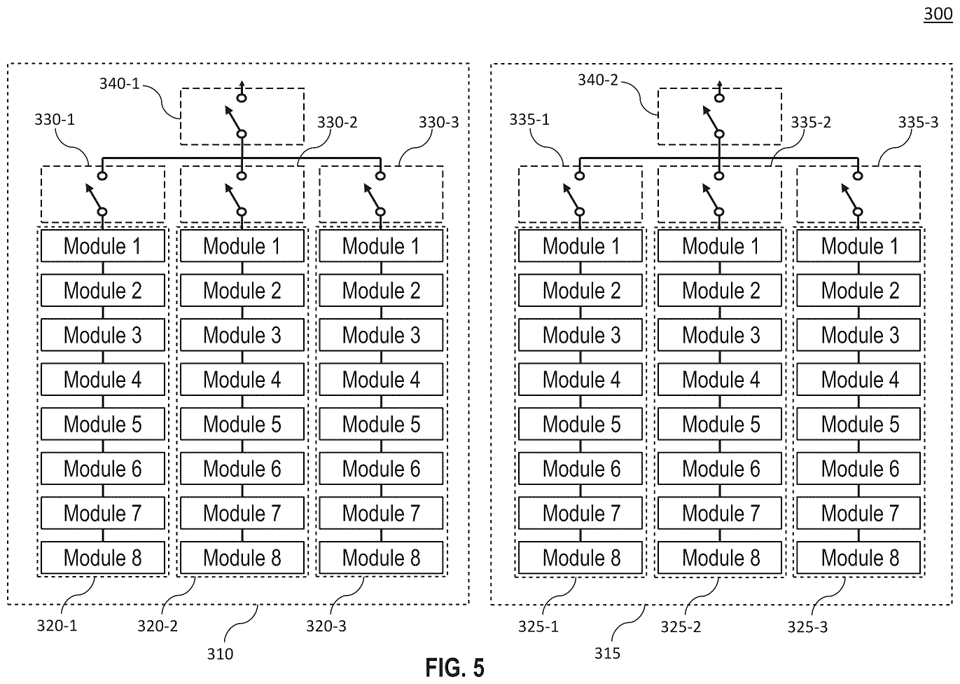

Referring to the drawings, the left most digit of a reference number identifies the drawing in which the reference number first appears (e.g., a reference number ‘310’ indicates that the element so numbered is first labeled or first appears in FIG. 5). Additionally, elements which have the same reference number, followed by a different letter of the alphabet or other distinctive marking (e.g., an apostrophe), indicate elements which may be the same in structure, operation, or form but may be identified as being in different locations in space or recurring at different points in time (e.g., reference numbers “102a” and “102b” may indicate two different devices which may be functionally the same, but may be located at different points in a simulation arena).

As used herein, the term “system” refers to mechanical and electrical hardware, software, firmware, electronic control componentry, processing logic, and/or processor device, individually or in combination, including without limitation: application specific integrated circuit (ASIC), an electronic circuit, a processor (shared, dedicated, or group) that executes one or more software or firmware programs, memory device(s) that electrically store software or firmware instructions, a combinatorial logic circuit, and/or other components that provide the described functionality.

As employed herein, terms such as “vertical”, “horizontal”, “left”, “right”, “upper”, “lower”, “top”, “bottom” and similar expressions are non-limiting terms that merely describe the various elements as illustrated in the Figures and are not intended to limit the scope of the disclosure.

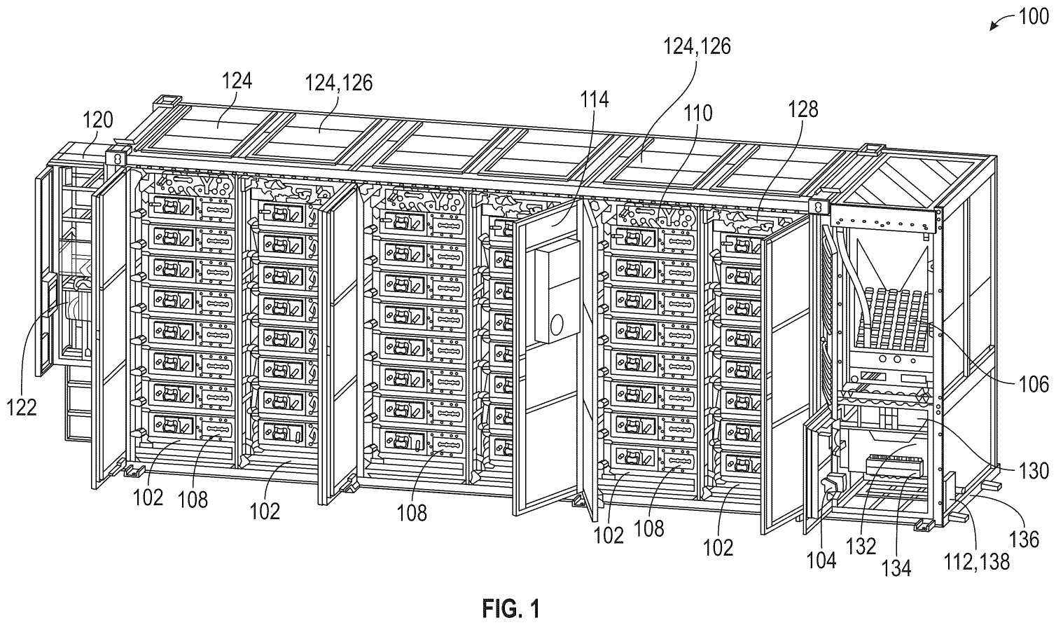

Referring to the drawings, FIG. 1 schematically illustrates an isometric view of an energy storage system 100, according to an embodiment of the present disclosure. The energy storage system 100 includes the plurality of energy storage enclosures 102, a controller 104, a cooling system (or chiller) 106 (which may be external or internal within an enclosure as would be known by one of ordinary skill in the art), multiple power conversion modules 108, multiple direct current protection modules (DCPM) 110, auxiliary components 112, a heating, ventilation, and air conditioning (HVAC) system 114, a fire panel 116, and plumbing 118. The energy storage system 100 may also include a DC disconnector box 120, a DC disconnect switch 122, multiple deflagration panels 124, multiple passive vents 126, a DC-DC converter 128, an uninterruptible power supply (UPS) 130, a master control board (MCB) 132, a power distributor 134, a grounding point 136, an enclosure to enclosure connections 138 and multiple battery modules 140. In various embodiments, the energy storage system 100 implements a battery energy storage system (BESS). In some embodiments, the energy storage system 100 may be one or more of a battery cell, a battery module, a battery pack, a battery enclosure, a battery node, and/or a battery core.

The plurality of energy storage enclosures 102 may be coupled to one another electrically. The plurality of energy storage enclosures 102, individually and collectively, may operate to store alternating current (AC) power delivered from an external power source 150 as direct current (DC) energy, for example but not limited to when the demand for power from the external power source 150 is lower than the external power source 150 is operable to generate, and/or to provide AC power to the external power source 150, for example, when the demand for power is higher than the external power source 150 may generate to provide the additional power. It should be appreciated that the plurality of energy storage enclosures 102 may be coupled to one another not only electrically, but also mechanically, and/or fluidly.

To facilitate the conversion of AC power to DC power and DC power to AC power, the power conversion module 108 may be used to standardize power input and output between the plurality of energy storage enclosures 102 and the external power source 150. The power conversion module 108 may include a converter to convert AC power to DC power, and/or DC power to AC power.

The cooling system 106 may be coupled to the plurality of energy storage enclosures 102 and the controller 104. The external cooling system may provide coolant at a first temperature T₁ to the plurality of energy storage enclosures 102 through at least one input port and receive coolant from the plurality of energy storage units at a second temperature T₂ from at least output port, such that T₁ is lower than T₂.

The cooling system 106 may include, for example, a heat exchanging system having a pump, a condenser, a heat exchange, and a sump. It should be appreciated that the at least one input port and the at least one output port may include more than one input port and/or one output port, and each of which may be disposed in one or more of the multiple energy storage enclosures 102.

The external power source 150 may be coupled to the plurality of energy storage enclosures 102. The external power source 150 may be operable to provide AC power converted to DC power to the plurality of energy storage enclosures 102 to be stored as DC energy, and to receive AC power converted from DC power from the plurality of energy storage enclosures 102, as discussed above.

The controller 104 may be in communication with the plurality of energy storage enclosures 102, the power conversion module 108, the cooling system 106, and the external power source 150, and may be used to control the aforementioned plurality of energy storage enclosures 102, the power conversion module 108, the cooling system 106, and their communication with the external power source 150.

The term “controller” and related terms such as microcontroller, control module, module, control, control unit, processor and similar terms refer to one or various combinations of Application Specific Integrated Circuit(s) (ASIC), Field-Programmable Gate Array (FPGA), electronic circuit(s), central processing unit(s), e.g., microprocessor(s) and associated memory component(s) in the form of transitory and/or non-transitory computer readable storage medium (or memory) component(s) and storage devices (read only, programmable read only, random access, hard drive, etc.). The non-transitory computer readable storage medium/memory component may be capable of storing machine readable instructions in the form of one or more software or firmware programs or routines, combinational logic circuit(s), input/output circuit(s) and devices, signal conditioning and buffer circuitry and other components that may be accessed by one or more processors to provide a described functionality. Input/output circuit(s) and devices include analog/digital inverters and related devices that monitor inputs from sensors, with such inputs monitored at a preset sampling frequency or in response to a triggering event. Software, firmware, programs, instructions, control routines, code, algorithms, and similar terms mean controller-executable instruction sets including calibrations and look-up tables.

The energy storage enclosures 102 may each include one or more packs, and a plurality of battery modules disposed within each pack, according to an embodiment of the present disclosure. Further, each battery module may also contain multiple battery submodules that may house individual battery cells (not shown).

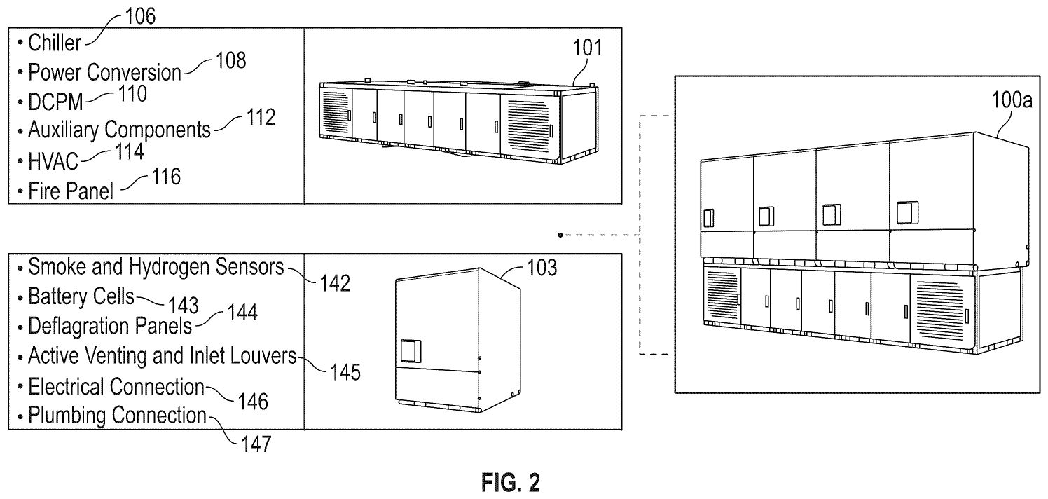

Referring to FIG. 2, a schematic isometric view of another energy storage system 100a is shown in accordance with one aspect of the disclosure. The energy storage system 100a generally includes a smartskid 101 and multiple (e.g., 4) pods 103 coupled to the smartskid 101. The smartskid 101 includes a cooling system 106, a power conversion module 108, a DCPM 110, auxiliary components 112, an HVAC 114 and a fire panel 116. Each pod 103 includes smoke and hydrogen sensor 142, battery cells 143, deflagration panels 144, active venting and inlet louvers 145, electrical connections 146 and plumbing connections 147.

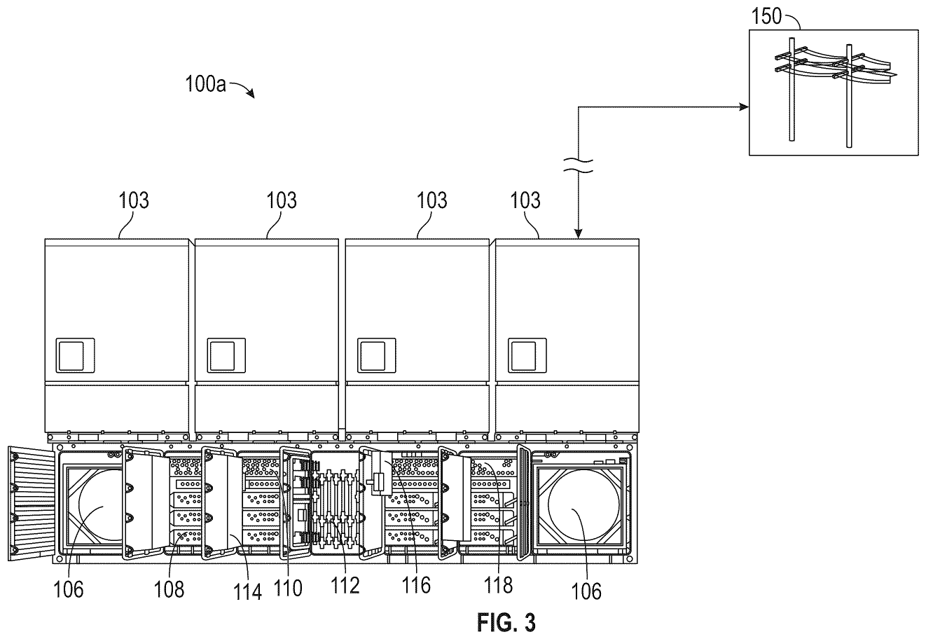

Referring to FIG. 3, a schematic front view of the energy storage system 100a is shown in accordance with one aspect of the disclosure. The smartskid 101 generally includes two cooling systems 106, the power conversion module 108, the DCPM 110, the auxiliary components 112, the HVAC 114, the fire panel 116 and plumbing 118. The energy storage system 100a (and 100 shown in FIG. 1) may be coupled with the external power source 150.

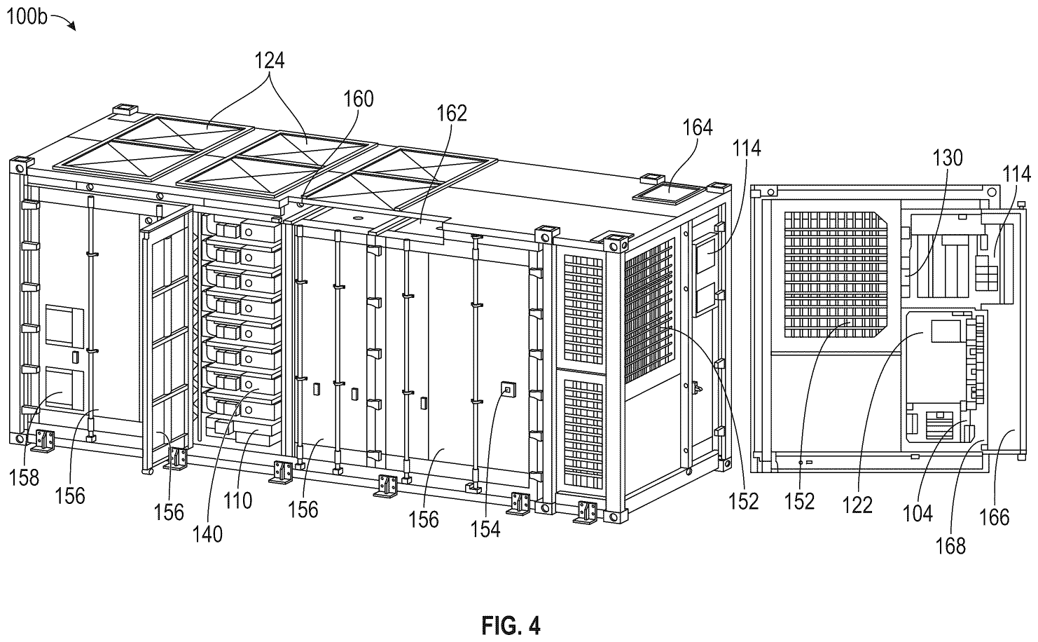

Referring to FIG. 4, a schematic isometric view of yet another energy storage system 100b is shown in accordance with one aspect of the disclosure. The energy storage system 100b generally includes the controller 104, the DCPM 110, the HVAC 114, the DC disconnect switch 122 the deflagration panels 124, the UPS 130, the battery modules 140, a chiller compartment 152, a fast stop (F-stop) 154, an enclosure door 156, an inlet louver 158, multi detectors 160, a hydrogen (H₂) gas detector 162, a vent panel 164, an enclosure side door 166, and a battery cooling plate (BCP) door 168.

FIG. 5 illustrates a diagram 300 of two direct current block enclosures with multiple parallel switched buses, according to an embodiment of the present disclosure. Diagram 300 illustrates an example single DC block enclosure 310 and DC block enclosure 315. An example of a single DC block enclosure 310 or DC block enclosure 315 may also be viewed as energy storage enclosure 102 discussed in FIG. 1. In an embodiment, a single DC block enclosure 310 or 315 may include one or more packs. In an embodiment, DC block enclosure 310, illustrated in FIG. 5, may include pack 320-1, pack 320-2, and pack 320-3 (collectively referred to as pack 320). Also shown is DC block enclosure 315 which may include pack 325-1, pack 325-2, and pack 325-3 (collectively referred to as pack 325). The number of packs within a set of packs is arbitrary and meant as an illustration of a possible configuration. For example, in other embodiments the number of total packs 320 and 325 may be more or less, for example, three, fifteen, or twenty. The concept of multiple packs, in this example pack 320 and pack 325 may be referred to as energy storage enclosures. Multiple packs may form a single enclosure or placed within a single container. In addition, multiple cubes/enclosures may be referred to as a node. Therefore, a node may contain one or more cubes. Multiple nodes may be grouped together into a core. And, multiple cores, for example at a client installation, may be referred to as a site (or array).

Further, each pack 320 and pack 325 may each contain multiple battery modules, labeled as module 1, module 2, module 3, module 4, module 5, module 6, module 7, and module 8. The number of packs and battery modules are purely examples and are not meant to limit the scope of the disclosure. In some embodiments, each pack 320 and pack 325 may contain hundreds of individual battery cells serially coupled and grouped into modules shown in FIG. 5.

Each pack 320 may also be coupled to a DC disconnector switch 330, and, in similar fashion, each pack 325 may also be coupled to a DC disconnector switch 335. Thus, as shown DC disconnector switch 330 may include DC disconnector switch 330-1, DC disconnector switch 330-2, and DC disconnector switch 330-3, each of which may be coupled to its corresponding pack 320-1, pack 320-2, and pack 320-3. Similarly, DC disconnector switch 335 may include DC disconnector switch 335-1, DC disconnector switch 335-2, and DC disconnector switch 330-3, each of which may be coupled to its corresponding pack 325-1, pack 325-2, and pack 325-3.

Finally, DC block enclosure 310 may also include a main DC box switch 340 for each of the packs. Thus, the main DC box switch 340-1 may be coupled to pack 320, which in this example includes pack 320-1, pack 320-2, and pack 320-3. Similarly, the main DC box switch 340-2 may be coupled to pack 325, which in this example includes pack 325-1, pack 325-2, and pack 325-3.

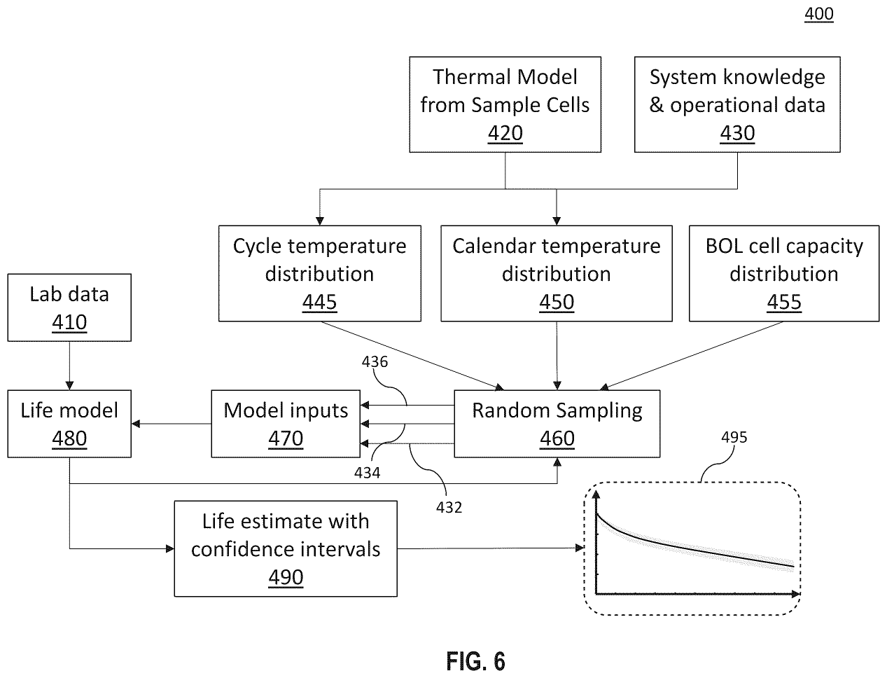

FIG. 6 illustrates a system-level battery degradation algorithm 400 for the generation of BESS life predictions at multiple system levels, according to an embodiment of the present disclosure. As described above, a battery energy storage system (BESS) may consist of multiple levels or layers of battery cells and components. For example, at the lowest or based level, a BESS may include a set of battery cells. A group of battery cells may be incorporated into a pack. One or more packs may be grouped into a physical enclosure or cube. Multiple cubes may be grouped into a node. Multiple nodes may be considered a core, and multiple cores may make up a site.

While battery performance may be calculated or estimated at the individual cell level, the performance of a BESS may also need to be viewed at the pack, node, core, and site levels. Thus, algorithm 400 is a system-level algorithm that is based on battery aging data, thermal data, systems-level knowledge to create a realistic BESS life prediction at multiple levels. Rather than relying on a battery supplier's possibly over-conservative battery life estimate, using this approach allows for a realistic life prediction across the multiple levels of a BESS.

Batteries lose capacity over time depending on how they are used. Battery life models may be used throughout industry and academia to predict how a battery's capacity will degrade under a variety of operating conditions. Battery life prediction methods may be classified into multiple categories, for example, model-based, data-driven, or hybrid. Model-based life prediction may use mathematical models that are fit to lab data to predict a battery cell life. Data-driven life predictions may take field data and apply artificial intelligence and/or machine learning techniques to predict life. Hybrid life prediction may be a combination of model-based and data-driven techniques.

However, in the case of a new BESS there is no field data as the systems may be constructed from battery cells that do not yet have associated field data. Thus, in this disclosure, the use of model-based life predictions may be used to predict multi-level system life through a life model. Model-based predictions may leverage battery lab data where a variety of operating conditions are tested and used to train the model. The trained model may then be used to make predictions on how battery capacity decays over time or under unique operating conditions.

However, for large grid-scale BESS systems, predicting a single battery's life may not be sufficient. Depending on how cells are connected, a single poor performing battery can limit the entire pack, enclosure/cube, or node. The algorithm and approach disclosed simulates variations between cells' capacity and cells' temperatures to predict life at the battery, pack, enclosure/cube node, core, and site levels. Such an approach may yield more realistic models than cell supplier guarantees.

Algorithm 400 describes a cell-level battery degradation algorithm that uses battery aging data, thermal data, and systems-level knowledge to create a realistic BESS life prediction for a battery cell within a BESS. Life model 480 includes a single battery life model that may be trained on lab data 410 where lab data 410 may be used to predict battery system performance prior to commissioning a battery. As there is no available field data for a new BESS, the life model 480 may be based and built from lab data 410 as one input with additional inputs, as will be described, from model inputs 470.

Model inputs 470 are based on thermal properties and predicted cell temperatures during cycling and during resting, i.e., calendar aging. This process may begin with a thermal model from sample cells 420 that may include a thermal model of a BESS enclosure and cell configuration that is built to predict the temperature of the cell under a variety of operating conditions. In addition, using system knowledge and operational data 430, variations of a cell temperature may be predicted based on differences in cell internal resistance, enclosure cooling design, cell manufacturer specifications, which may introduce some variation around the predictions from thermal model from sample cells 420. Thus, using system knowledge, test data, or operational data the distribution of cycling and calendar temperatures may be estimated resulting in a distribution of cell temperatures in cycle temperature distribution 445 and calendar temperature distribution 450.

There may also be some variation in each cell's beginning of life (BOL) capacity. BOL capacity typically varies due to manufacturing differences. The BOL energy distribution 455 may be estimated from end-of-line manufacturing data, experimental data, or field data during commissioning.

Once the cycle temperature distribution 445, calendar temperature distribution 450, and BOL cell energy distribution 455 are defined the distributions may be randomly sampled, as illustrated by Random Sampling 460, to obtain a random value for cycle temperature 432, calendar temperature 434, and cell capacity 436 which may then be defined as model inputs 470 which may then be input into the life model 480. The life model 480 may then be run with these conditions as well as additional defined operating conditions, for example, ambient temperature, CP-rate, cycles/day, changes in thermal strategy (e.g., chiller setpoints, flow rate, compressor size), etc., where a life curve may be generated.

Multiple cells may be simulated by repeating the random sampling process, e.g., returning to random sampling 460 and obtaining a new cycle temperature, a new calendar temperature, and a new BOL cell capacity, to generate a set of new model inputs 470 and rerunning the life model 480. This process may be repeated for however many cells desired to be simulated thereby generating a life estimate with confidence intervals 490 and charted as shown in chart 495.

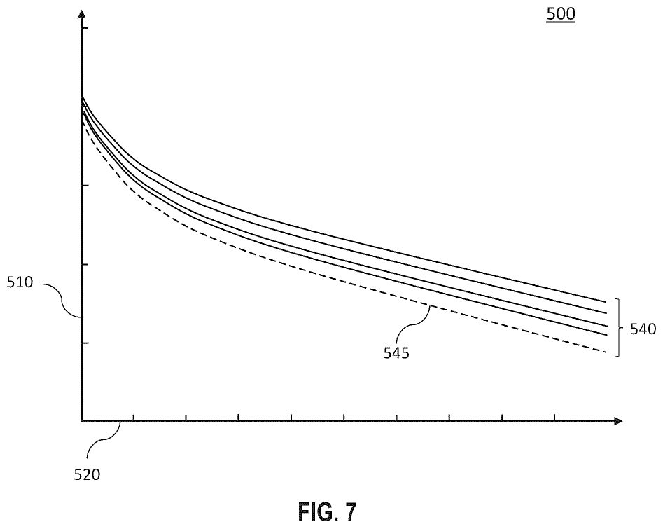

FIG. 7 illustrates a cell life state of health scenario 500, according to an embodiment of the present disclosure. Scenario 500 illustrates a set of degradation curves that graph the state of health of multiple cells as predicted and illustrated in FIG. 6 with axis 510 charting the state of health against axis 520 charting time. Each curve in the set of degradation curves 540 represents the state of health of an individual cell.

As discussed in FIG. 6, the described process is directed to simulating degradation at the cell level. The transition from the base cell model to a pack model, an enclosure/cube model, a node model, a core model, and a site level model may be derived from the cell level algorithm discussed in FIG. 6. For example, a pack may be made up of multiple base cells connected in series. As each pack includes multiple cells connected in series, the performance of that pack may be limited by the worst performing cell. Thus, the number of cells per pack may be simulated as shown by the set of degradation curves 540 where the worst performing cell, as shown be degradation curve 545, may represent the pack energy. For example, in a scenario with 400 cells per pack, 400 cell simulations may be run where the cell with the most degradation (lowest state of health, SOH) may be used for the pack degradation curve.

A cube may include multiple packs. Further, a cube may include the scenario where the packs are connected in parallel. However, each cube may be limited by the worst performing pack. For example, in a scenario with twenty packs per cube, twenty pack simulations may be run where the pack with the most degradation may be used for the cube degradation curve. A node may include multiple cubes. However, each node may be limited by the worst performing cube.

A core may include multiple nodes connected in parallel where each node is designed with an inverter to generate alternating current. Thus, a core may not be limited by the worst performing node and a core level simulation may be the sum of simulated node level energy. Further, a site may be the sum of all simulated core energy.

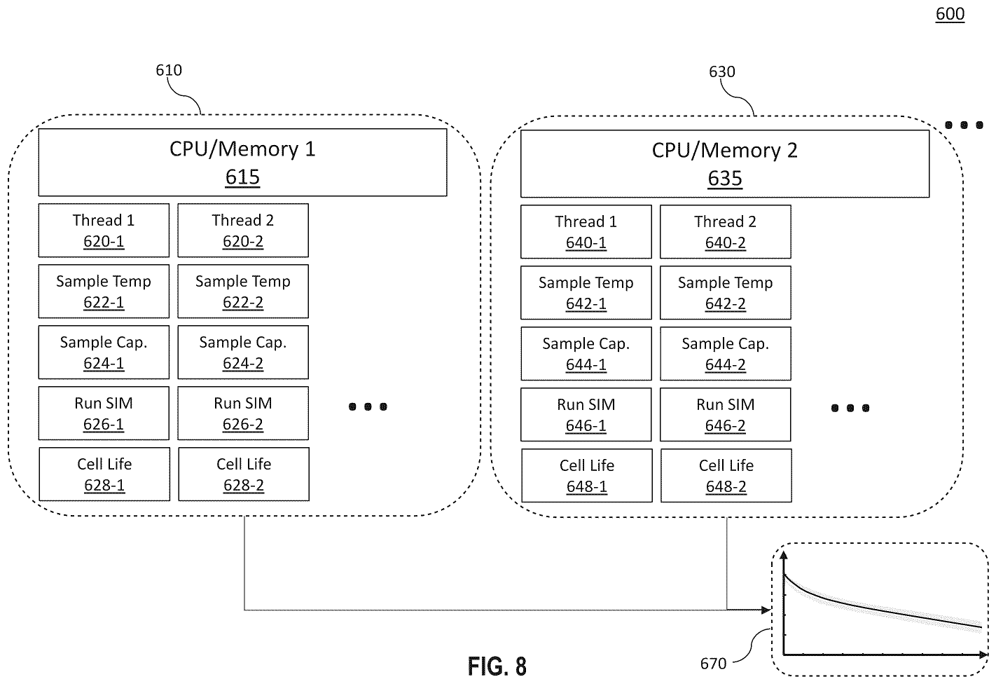

FIG. 8 is an illustration of a multiprocessing and multithreading technique 600 for a system-level battery degradation algorithm, according to an embodiment of the present disclosure. As discussed above, a single pack may include 400 or more individual battery cells. A cube may include, for example, two, four, six, eight or ten packs connected in parallel. A node may include, for example, six, fifteen, or twenty cubes connected in parallel. A core may include multiple nodes connected in parallel, and a site may include multiple cores. Thus, a site may include thousands or millions of cells. Thus, the computational process of scaling up from a cell to a pack, to a cube, to a node, to a core, and to a site may be very computationally intensive if not properly structured. To improve computation time, a combination of multiprocessing and multithreading techniques may be used as shown in FIG. 8. Technique 600 includes multi-processing systems 610 and 630, with multithreading using central processing units and memory, for example, CPU/Memory 1 615 and CPU/Memory 2 635. While two CPUs are shown, any number of processors, memory, and other supporting architecture in a computer, server, or cloud computing environment may be used as would be known to one of ordinary skill in the art.

A controller or computing system may receive real-time operational data from the BESS, including temperature, current voltage and state-of charge data from the individual battery modules and packs. Each individual cell simulation may be treated as a unique thread. Thus, each thread 620, shown as thread 1 620-1 and thread 2 620-2, through to thread N 620-N (not shown) represents a single battery cell that may be simulated utilizing CPU/Memory 1 615. In the same manner each thread 640, shown as thread 1 640-1 and thread 2 640-2, through to thread N 640-N (not shown) represents a single battery cell that may be simulated utilizing CPU/Memory 2 635.

Further, each thread for each cell may also contain additional information needed to perform the cell-level battery degradation algorithm discussed in FIG. 6 where the temperatures and cell capacity are randomly sampled, and a cell life curve is generated. For example, a sample temperature 622-1, a sample capacity 624-1, simulation results 626-1, and cell life model 628-1. The same information for the other threads across the various CPU/memory multiprocessing architecture is also shown including a sample temperature 622-2, a sample capacity 624-2, simulation results 626-2, and cell life model 628-2; a sample temperature 642-1, a sample capacity 644-1, simulation results 646-1, and cell life model 648-1; and a sample temperature 642-2, a sample capacity 644-2, simulation results 646-2, and cell life model 648-2. The cell life models 648-1 and 648-2 may establish a life estimate graph 670 with confidence intervals. The hierarchical life model may process operational data together with laboratory-derived degradation parameters to estimate remaining useful life (RUL) at the cell, pack, enclosure/cube, node, core, and site levels. Predictions may be updated periodically or continuously.

In an embodiment, to further reduce computational time the cell simulation may be run if the sampled temperatures or capacity are worse than the previous simulation. This type of approach prevents every cell from being simulated, only cells that are likely to be poor performers will be simulated. Further, each pack may be treated as a unique process such that multiple packs may be run in parallel. The life model may employ Monte Carlo sampling of temperature and capacity distributions to propagate uncertainty across hierarchical levels. Parallel processing, including multiprocessing and multithreading computations, may be used to accelerate the simulations.

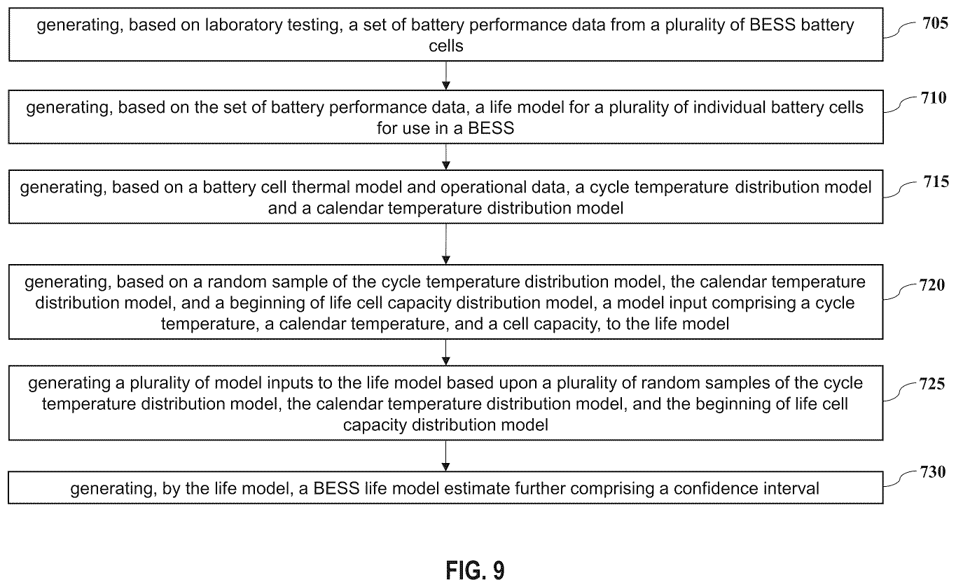

FIG. 9 illustrates method 700 for battery energy storage system (BESS) life model estimation, according to an embodiment of the present disclosure. FIG. 9 may begin with step 705 with generating, based on laboratory testing, a set of battery performance data from a plurality of BESS battery cells. As discussed in FIG. 6, life model 480 includes a single battery life model that may be trained on lab data 410, where lab data 410 may be used to predict battery system performance prior to commissioning a battery. As there is no available field data life model 480 may be based and built from lab data 410 as one input with additional inputs, as will be described, from model inputs 470. Estimated life results and associated confidence intervals may be communicated to the BESS controller, which may optionally adjust operational parameters such as a charge rate, a discharge rate, a depth of discharge, one or more cooling setpoints, and a module-level balancing to extend overall system life.

At step 710, the method may continue by generating, based on the set of battery performance data, a life model for a plurality of individual battery cells for use in a BESS. As discussed in FIG. 6, life model 480 utilizes laboratory experimental data to define the characteristics of a single battery cell. However, life model 480 also may utilize additional data input from model inputs 470 that may be based on a random sampling of temperature distribution data, for example, from cycle temperature distribution 445 and calendar temperature distribution 450. Model inputs 470 may also be based on random sampling of BOL cell capacity distribution 455. In some embodiments, life model 480 may also be based on other defined operating conditions, for example, ambient temperature, CP-rate, cycles/day, etc.

At step 715, the method may continue with generating, based on a battery cell thermal model and operational data, a cycle temperature distribution model, and a calendar temperature distribution model. As mentioned in step 710, life model 480 utilizes temperature distribution data where temperature distribution data may be based on thermal models such as with a thermal model from sample cells 420 that may include a thermal model of a BESS enclosure and cell configuration that is built to predict the temperature of the cell under a variety of operating conditions. Temperature distribution data may be based on using system knowledge and operational data 430, for example, variations of a cell temperature may be predicted based on differences in cell internal resistance, enclosure cooling design, cell manufacturer specifications, which may introduce some variation around the predictions from thermal model from sample cells 420.

At step 720, the method may continue by generating, based on a random sample of the cycle temperature distribution model, the calendar temperature distribution model, and a beginning of life cell capacity distribution model, a model input comprising a cycle temperature, a calendar temperature, and a cell capacity, to the life model. As discussed in FIG. 6, life model 480 utilizes a random sampling of temperature distributions and a BOL cell capacity distribution. As discussed, the BOL energy distribution 455 may be estimated from end-of-line manufacturing data, experimental data, or field data during commissioning.

At step 725, the method may continue by generating a plurality of model inputs to the life model based upon a plurality of random samples of the cycle temperature distribution model, the calendar temperature distribution model, and the beginning of life cell capacity distribution model. As discussed with FIG. 6, multiple cells may be simulated by repeating the random sampling process, e.g., returning to random sampling 460 and obtaining a new cycle temperature, a new calendar temperature, and a new BOL cell capacity, to generate a set of new model inputs 470 and rerunning the life model 480. For example, in a scenario with 400 cells per pack, 400 cell simulations may be run where the cell with the most degradation (lowest state of health, SOH) may be used for the pack degradation curve.

At step 730, the method may continue by generating, by the life model, a BESS life model estimates further comprising a confidence interval. As discussed with FIG. 6, and in step 725, the process of randomly sampling temperature distribution data and BOL distribution data may produce a range of results from life model 480. Thus, as the process may be repeated for however many cells desired to be simulated thereby generating a life estimate with confidence intervals 490 and charted as shown in chart 495.

Method 700 may then end.

The description and abstract sections may set forth one or more embodiments of the present disclosure as contemplated by the inventor(s), and thus, are not intended to limit the present disclosure and the appended claims.

Embodiments of the present disclosure have been described above with the aid of functional building blocks illustrating the implementation of specified functions and relationships thereof. The boundaries of these functional building blocks have been arbitrarily defined herein for the convenience of the description. Alternate boundaries may be defined so long as the specified functions and relationships thereof may be appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present disclosure should not be limited by the above-described exemplary embodiments.

Exemplary embodiments of the present disclosure have been presented. The disclosure is not limited to these examples. These examples are presented herein for purposes of illustration, and not limitation. Alternatives (including equivalents, extensions, variations, deviations, etc., of those described herein) will be apparent to persons skilled in the relevant art(s) based on the teachings contained herein. Such alternatives fall within the scope and spirit of the disclosure.

What is claimed is:

1. A method for estimating and controlling a battery energy storage system (BESS) life model, the method comprising:
receiving, by a controller, a BESS life model that estimates an expected remaining useful life of the BESS at multiple hierarchical levels, wherein the BESS life model is generated by a process comprising:
constructing a cell-level degradation model based on laboratory test data representing degradation behavior of a plurality of battery cells, wherein the degradation model accounts for variations in cell capacity, internal resistance, and temperature-dependent aging;
generating a plurality of cell life predictions by executing a Monte Carlo simulation that provides, as inputs to the cell-level degradation model, a plurality of random samples from a cycle temperature distribution, a calendar temperature distribution, and a beginning-of-life cell capacity distribution;
aggregating the plurality of cell life predictions into a plurality of pack life models for a plurality of battery packs within the BESS by selecting a worst-performing cell based on predicted remaining useful life;
aggregating the plurality of pack life models into a node life model for a node within the BESS, wherein the node comprises multiple parallel-coupled ones of the plurality of battery packs; and
generating a system-level life estimate, including a statistical confidence interval, based on the node life model; and
adjusting, by the controller, an operational parameter of the BESS based on the received BESS life model, wherein the operational parameter comprises one or more of a charge rate, a discharge rate, a depth of discharge, a cooling system setpoint, and a module-level balancing.

2. The method as recited in claim 1, further comprising generating, by the life model, a plurality of module life models for a plurality of modules within the BESS, wherein each of the plurality of modules comprises multiple ones of the plurality of battery cells.

3. The method as recited in claim 2, further comprising generating, by the life model, at least two pack life models for at least two packs within the BESS, wherein each of the at least two packs comprises multiple parallel-coupled ones of the plurality of modules.

4. The method as recited in claim 3, further comprising generating, by the life model, at least two cube life models for at least two cubes within the BESS, wherein each of the at least two cubes comprises multiple parallel-coupled ones of the at least two packs.

5. The method as recited in claim 4, further comprising generating, by the life model, at least two node life models for at least two nodes within the BESS, wherein each of the at least two nodes comprises multiple parallel-coupled ones of the at least two cubes.

6. The method as recited in claim 5, further comprising generating, by the life model, at least two core life models for at least two cores within the BESS, wherein each of the at least two cores comprises multiple parallel-coupled one of the at least two nodes.

7. The method as recited in claim 3, wherein each of the at least two pack life models is based on a worst performing cell within the respective pack.

8. The method as recited in claim 4, wherein each of the at least two cube life models is based on a worst performing pack within the respective cube.

9. The method as recited in claim 3, wherein each of the at least two pack life models is based on an additional Monte Carlo simulation.

10. The method as recited in claim 9, wherein the additional Monte Carlo simulation is based upon a combination of multiprocessing and multithreading computations.

11. A system for estimating and controlling a battery energy storage system (BESS) life model, the system comprising:
a controller operational to receive a BESS life model that estimates an expected remaining useful life of the BESS at multiple hierarchical levels, wherein the BESS life model is generated by a process comprising:
constructing a cell-level degradation model based on laboratory test data representing degradation behavior of a plurality of battery cells, wherein the degradation model accounts for variations in cell capacity, internal resistance, and temperature-dependent aging;
generating a plurality of cell life predictions by executing a Monte Carlo simulation that provides, as inputs to the cell-level degradation model, a plurality of random samples from a cycle temperature distribution, a calendar temperature distribution, and a beginning-of-life cell capacity distribution;
aggregating the plurality of cell life predictions into a plurality of pack life models for a plurality of battery packs within the BESS by selecting a worst-performing cell based on predicted remaining useful life;
aggregating the plurality of pack life models into a node life model for a node within the BESS, wherein the node comprises multiple parallel-coupled ones of the plurality of battery packs; and
generating a system-level life estimate, including a statistical confidence interval, based on the node life model; and
the controller is further operational to adjust an operational parameter of the BESS based on the received BESS life model, wherein the operational parameter comprises one or more of a charge rate, a discharge rate, a depth of discharge, a cooling system setpoint, and a module-level balancing.

12. The system as recited in claim 11, wherein the controller is further configured to generate, by the life model, a plurality of module life models for a plurality of modules within the BESS, wherein each of the plurality of modules comprises multiple ones of the plurality of battery cells.

13. The system as recited in claim 12, wherein the controller is further configured to generate, by the life mode, at least two pack life models for at least two packs within the BESS, wherein each of the at least two packs comprises multiple parallel-coupled ones of the plurality of modules.

14. The system as recited in claim 13, wherein the controller is further configured to generate, by the life module, at least two cube life models, for at least two cubes within the BESS, wherein each of the at least two cubes comprises multiple parallel-coupled ones of the at least two packs.

15. The system as recited in claim 14, wherein the controller is further configured to generate, by the life module, at least two node life models, for at least two nodes within the BESS, wherein each of the at least two nodes comprises multiple parallel-coupled ones of the at least two cubes.

16. The system as recited in claim 15, wherein the controller is further configured to generate, by the life module, at least two core life models for at least two cores within the BESS, wherein each of the at least two nodes comprises multiple parallel-coupled ones of the at least two cubes.

17. The system as recited in claim 13, wherein each of the at least two pack life models is based on a worst performing cell within the respective pack.

18. The system recited in claim 14, wherein each of the at least two node life models is based on a worst performing pack within the respective node.

19. The system as recited in claim 15, wherein each of the at least two pack life models is based on an additional Monte Carlo simulation.

20. A method for battery energy storage system (BESS) life model estimation comprising:
generating, based on laboratory testing, a set of battery performance data from a plurality of BESS battery cells;
generating, based on the set of battery performance data, a life model for a plurality of individual battery cells for use in a BESS;
generating, based on a battery cell thermal model and operational data, a cycle temperature distribution model, and a calendar temperature distribution model;
generating, based on a random sample of the cycle temperature distribution model, the calendar temperature distribution model, and a beginning of life cell capacity distribution model, a model input comprising a cycle temperature, a calendar temperature, and a cell capacity, to the life model;
generating a plurality of model inputs to the life model based upon a plurality of random samples of the cycle temperature distribution model, the calendar temperature distribution model, and the beginning of life cell capacity distribution model;
generating, by the life model, a BESS life estimate further comprising a confidence interval;
generating, by the life model, a base life model based on a plurality of battery cells;
generating, by the life model, a pack life model, for a pack within a BESS, wherein the pack comprises a plurality of series coupled battery modules and wherein each battery module comprises a plurality of battery cells;
generating, by the life model, a node life model for a node within a BESS, wherein the node comprises a plurality of parallel coupled packs; and
generating, by the life model, a core life model for a core within a BESS, wherein the core comprises a plurality of parallel coupled nodes;
wherein the plurality of parallel coupled nodes are electrically coupled comprising alternating current,
wherein the pack life model is based on a worst performing cell within the pack, and
wherein the node life model is based on a worst performing pack of the plurality of parallel coupled packs within the node.
